(19) United States
(12) Patent Application Publication
(10) Pub. No.: US 2026/0336396 A1
(43) Pub. Date: Oct. 29, 2026

(54) VEHICLE AND CONTROL METHOD THEREOF

(71) Applicant: HL MANDO CORPORATION, Pyeongtaek-si (KR)

(72) Inventor: Taehoon KIM, Pyeongtaek-si (KR)

(73) Assignee: HL MANDO CORPORATION, Pyeongtaek-si (KR)

(21) Appl. No.: 19/366,708

(22) Filed: Oct. 23, 2025

(30) Foreign Application Priority Data
Apr. 28, 2025 (KR) 10-2025-0055792

(51) Int. Cl. B60K 26/04; G01R 19/165; G07C 5/02

(52) U.S. Cl. CPC B60K 26/04; G01R 19/1659; G07C 5/02; B60K 2026/046

(57) ABSTRACT

A vehicle comprises a first throttle position sensor; a second throttle position sensor; and a controller configured to: identify whether a first change amount of the voltage value obtained from the first throttle position sensor and a second change amount of the voltage value obtained from the second throttle position sensor are within a predetermined threshold range of a voltage change amount, and control the vehicle based on a voltage value obtained from at least one of the first throttle position sensor or second throttle position sensor in response to at least one of the first change amount or the second change amount being within the predetermined threshold range of the voltage change amount.

### CROSS-REFERENCE TO RELATED APPLICATIONS

This application claims the priority of Korean Patent Application No. 10-2025-0055792 filed on Apr. 28, 2025, in the Korean Intellectual Property Office, the disclosure of which is incorporated herein by reference.

### BACKGROUND

### Field

The present disclosure relates to a vehicle and a control method thereof, and more particularly, to a throttle of the vehicle.

### Description of the Related Art

The vehicle includes two-wheeled and four-wheeled vehicles such as internal combustion engine motorcycles, electric motorcycles, and/or electric bicycles, and such vehicles are equipped with a throttle.

The throttle plays an important role in generating a required torque that reflects the driver's intention for controlling the acceleration of the vehicle.

In the case of two-wheeled vehicles, the throttle is mounted on the handlebar, which the driver can directly operate. When the throttle is operated by the driver, the engine speed of the two-wheeled vehicle may increase, which in turn leads to an increase in the vehicle's speed.

For example, when the throttle is operated by the driver, the controller can obtain a voltage value corresponding to the displacement of the throttle from the throttle position sensor, and based on this, control the engine output.

Accurate control of the engine output based on the voltage value obtained from the throttle position sensor enables stable driving of the two-wheeled vehicle, and therefore, the throttle position sensor is closely related to the stability of the two-wheeled vehicle.

Accordingly, the development of technology capable of coping with the malfunction of the throttle position sensor, that is, its failure, has been required.

Conventionally, technology has been developed to automatically limit engine output when the throttle position sensor fails, but such technology has been pointed out to have the drawback of potentially limiting the control of the two-wheeled vehicle in emergency situations.

Therefore, the development of new technology that improves the drawbacks of the conventional technology is required.

### SUMMARY

One aspect of the present disclosure may provide a vehicle and its control method that configure two throttle position sensors outputting voltage values corresponding to the displacement of the throttle, and provide a redundancy function through the other sensor that operates normally even when one sensor fails, thereby enabling the vehicle to travel safely.

Accordingly, the vehicle and its control method of the present disclosure allow the vehicle to perform smooth and stable control even when one of the two throttle position sensors fails, so that the driver can experience a high level of ride comfort and the safety of the vehicle can be improved.

According to one aspect of the present disclosure, there is provided a vehicle comprising:
a first throttle position sensor configured to output a voltage value corresponding to a displacement of a throttle;
a second throttle position sensor configured to output a voltage value corresponding to a displacement of the throttle; and
a controller electrically connected to the first throttle position sensor and the second throttle position sensor, wherein the controller is configured to:
identify whether a first change amount of the voltage value obtained from the first throttle position sensor and a second change amount of the voltage value obtained from the second throttle position sensor are within a predetermined threshold range of a voltage change amount, and control the vehicle based on a voltage value obtained from at least one of the first throttle position sensor or second throttle position sensor in response to at least one of the first change amount or the second change amount being within the predetermined threshold range of the voltage change amount.

The controller may determine a required torque of the vehicle based on the voltage value obtained from at least one of the first throttle position sensor or second throttle position sensor, and control a speed of the vehicle based on the required torque.

The controller may identify the first change amount and the second change amount based on a difference between the voltage value obtained from the first throttle position sensor and the voltage value obtained from the second throttle position sensor exceeding a predetermined threshold value.

The controller may control speed of the vehicle, based on an average value of the voltage value obtained from the first throttle position sensor and the voltage value obtained from the second throttle position sensor, in response to the difference between the voltage value obtained from the first throttle position sensor and the voltage value obtained from the second throttle position sensor being less than or equal to the predetermined threshold value.

The controller may control speed of the vehicle, based on an average value of the voltage value obtained from the first throttle position sensor and the voltage value obtained from the second throttle position sensor, in response to the first change amount and the second change amount being within the predetermined threshold range.

The controller may control speed of the vehicle, based on the voltage value obtained from the first throttle position sensor, in response to the first change amount being within the predetermined threshold range and the second change amount not being within the predetermined threshold range.

The controller may control speed of the vehicle, based on the voltage value obtained from the second throttle position sensor, in response to the first change amount not being within the predetermined threshold range and the second change amount being within the predetermined threshold range.

The controller may control the vehicle in a predetermined fault mode, in response to the first change amount and the second change amount not being within the predetermined threshold range.

The controller may determine a required torque of the vehicle to be zero, in response to the first change amount and the second change amount not being within the predetermined threshold range.

The controller may control an output device of the vehicle to output a notification indicating that the first throttle position sensor and the second throttle position sensor are in a fault state, in response to the first change amount and the second change amount not being within the threshold range.

According to one aspect of the present disclosure, there is provided a control method of vehicle comprises identifying whether a first change amount of the voltage value obtained from a first throttle position sensor configured to output a voltage value corresponding to a displacement of a throttle and a second change amount of the voltage value obtained from a second throttle position sensor configured to output a voltage value corresponding to a displacement of the throttle are within a predetermined threshold range of a voltage change amount, and controlling the vehicle based on a voltage value obtained from at least one of the first throttle position sensor or second throttle position sensor in response to at least one of the first change amount or the second change amount being within the predetermined threshold range of the voltage change amount.

The controlling of the vehicle may comprise
determining a required torque of the vehicle based on the voltage value obtained from at least one of the first throttle position sensor or second throttle position sensor, and controlling a speed of the vehicle based on the required torque.

The control method may further comprise
identifying the first change amount and the second change amount based on a difference between the voltage value obtained from the first throttle position sensor and the voltage value obtained from the second throttle position sensor exceeding a predetermined threshold value.

The control method may further comprise
controlling speed of the vehicle, based on an average value of the voltage value obtained from the first throttle position sensor and the voltage value obtained from the second throttle position sensor, in response to the difference between the voltage value obtained from the first throttle position sensor and the voltage value obtained from the second throttle position sensor being less than or equal to the predetermined threshold value.

The controlling of the speed of the vehicle may be performed based on an average value of the voltage value obtained from the first throttle position sensor and the voltage value obtained from the second throttle position sensor, in response to the first change amount and the second change amount being within the predetermined threshold range.

The controlling of the speed of the vehicle may be performed based on the voltage value obtained from the first throttle position sensor, in response to the first change amount being within the predetermined threshold range and the second change amount not being within the predetermined threshold range.

The controlling of the speed of the vehicle may be performed based on the voltage value obtained from the second throttle position sensor, in response to the first change amount not being within the predetermined threshold range and the second change amount being within the predetermined threshold range.

The control method may further comprise
controlling the vehicle in a predetermined fault mode, in response to the first change amount and the second change amount not being within the predetermined threshold range.

The controlling of the vehicle in the predetermined fault mode may comprise
determining a required torque of the vehicle to be zero.

The controlling of the vehicle in the predetermined fault mode may comprise
controlling an output device of the vehicle to output a notification indicating that the first throttle position sensor and the second throttle position sensor are in a fault state.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram showing a part of the configuration of a vehicle according to an embodiment.

FIG. 2 is a flowchart of the operation of a vehicle according to an embodiment.

FIG. 3 is a flowchart of the operation of a vehicle according to an embodiment.

### DETAILED DESCRIPTION OF THE EMBODIMENT

Hereinafter, the exemplary embodiment of the present disclosure will be described with reference to the accompanying drawings and exemplary embodiments as follows. Scales of components illustrated in the accompanying drawings are different from the real scales for the purpose of description, so that the scales are not limited to those illustrated in the drawings.

Like reference numerals refer to like elements throughout the specification. The present specification does not describe all elements of the embodiments, and any content that is general in the technical field to which the present disclosure belongs or that overlaps between the embodiments is omitted.

The terms “portion, module, element, or block” used in the specification may be implemented in software or hardware, and according to the embodiments, a plurality of “portions, modules, elements, or blocks” may be implemented as a single element, or a single “portion, module, element, or block” can include a plurality of elements.

Throughout the specification, when a part is said to be “connected” to another part, this includes not only direct connection but also indirect connection, and indirect connection includes connection via a wireless communications network.

Additionally, when a part is said to “include” a component, this does not mean that it excludes other components, unless otherwise specifically stated, but rather that it may include other components.

Throughout the specification, when it is said that an element is located “on” another element, this includes not only cases where an element is in contact with another element, but also cases where another element exists between the two elements.

The terms first, second, and the like are used to distinguish one component from another, and the components are not limited by the aforementioned terms.

Singular expressions include plural expressions unless the context clearly indicates otherwise.

The identification codes in each step are used for convenience of explanation and do not describe the order of each step. Each step may be performed in a different order than specified unless the context clearly indicates a specific order.

An embodiment of the disclosed invention is to provide a vehicle and its control method for improving vehicle stability.

For example, an embodiment of the disclosed invention aims to improve vehicle stability by proposing a redundancy system that duplicates throttle position sensors outputting voltage values according to throttle displacement.

For example, the vehicle in an embodiment of the disclosed invention may include two-wheeled and/or four-wheeled vehicles such as internal combustion motorcycles, electric motorcycles, and/or electric bicycles.

Hereinafter, the operating principle and embodiments of the present disclosure will be described with reference to the attached drawings.

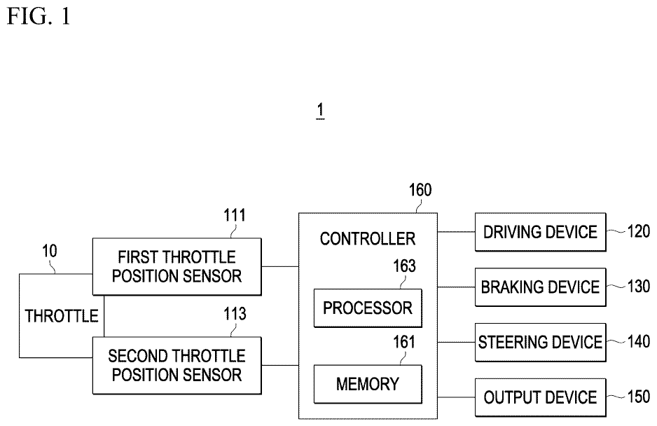

FIG. 1 is a block diagram showing a part of the configuration of a vehicle according to an embodiment.

Referring to FIG. 1, the vehicle 1 may include a throttle 10, a first throttle position sensor 111, a second throttle position sensor 113, a driving device 120, a braking device 130, a steering device 140, an output device 150, and/or a controller 160.

The throttle 10 is a device that receives the driver's operation input for controlling the acceleration of the vehicle 1.

For example, when the vehicle 1 is a two-wheeled vehicle, the throttle 10 may be provided on the handlebar of the vehicle 1. When the driver performs an operation such as turning the handlebar of the vehicle 1, the throttle valve may open, increasing the amount of air flowing into the engine of the vehicle 1, and accordingly, the engine output may increase.

As another example, when the vehicle 1 is a four-wheeled vehicle, the throttle 10 may be provided on the accelerator pedal of the vehicle 1.

When the driver performs an operation such as pressing the accelerator pedal of the vehicle 1, the throttle valve may open, increasing the amount of air flowing into the engine of the vehicle 1, and accordingly, the engine output may increase.

The first throttle position sensor 111 and the second throttle position sensor 113 may be provided on a part of the throttle 10, respectively, and may output voltage values corresponding to the displacement of the throttle 10.

The voltage values output by the first and second throttle position sensors 111 and 113, respectively, may be transmitted to the controller 160 and used to control the speed of the vehicle 1.

The driving device 120 may provide power for the vehicle 1 to travel and may increase or decrease the speed of the vehicle 1.

For example, the driving device 120 may include an internal combustion engine and/or an electric motor, and the speed of the vehicle 1 may be controlled by the power generated by the internal combustion engine and/or the electric motor.

The braking device 130 may provide braking force for the vehicle 1 to perform braking.

For example, when the vehicle 1 is a two-wheeled vehicle, the braking device 130 may decelerate or stop the vehicle 1 in response to the braking intention according to the operation of the driver's brake lever (not shown).

As another example, when the vehicle 1 is a four-wheeled vehicle, the braking device 130 may decelerate or stop the vehicle 1 in response to the braking intention according to the pressing of the driver's brake pedal (not shown).

The braking device 130 may be implemented with various brake devices such as a disc brake or a drum brake.

The steering device 140 may change the traveling direction of the vehicle 1.

For example, when the vehicle 1 is a two-wheeled vehicle, the steering device 140 may change the traveling direction of the vehicle 1 in response to the driver's steering intention through the handlebar of the vehicle 1.

As another example, when the vehicle 1 is a four-wheeled vehicle, the steering device 140 may change the traveling direction of the vehicle 1 in response to the driver's steering intention through the steering of the vehicle 1.

The output device 150 may output visual and/or auditory information.

For example, the output device 150 may include a display and/or a speaker, and may output information so that the driver can check the corresponding information.

The controller 160 (also referred to as a control circuit) may control the vehicle 1 overall.

The controller 160 is electrically or communicatively connected to each component of the vehicle 1, for example, the first throttle position sensor 111, the second throttle position sensor 113, the driving device 120, the braking device 130, the steering device 140, and/or the output device 150, and may control each component.

The controller 160 may acquire voltage values from the first throttle position sensor 111 and the second throttle position sensor 113 respectively according to the driver's operation of the throttle 10.

For example, the controller 160 may acquire voltage values corresponding to the displacement of the throttle 10 from the first throttle position sensor 111 and the second throttle position sensor 113 respectively each time the driver operates the throttle 10 during the traveling of the vehicle 1.

The controller 160, based on the voltage value acquired from the first throttle position sensor 111 and the voltage value acquired from the second throttle position sensor 113, may determine whether the states of the first throttle position sensor 111 and the second throttle position sensor 113 are normal states or fault states.

The controller 160 may determine that the first throttle position sensor 111 and the second throttle position sensor 113 are in normal states when the difference between the voltage value acquired from the first throttle position sensor 111 and the voltage value acquired from the second throttle position sensor 113 is equal to or less than a predetermined threshold value.

The controller 160 may determine that the first throttle position sensor 111 and/or the second throttle position sensor 113 are in a fault state when the difference between the voltage value acquired from the first throttle position sensor 111 and the voltage value acquired from the second throttle position sensor 113 exceeds the predetermined threshold value according to the driver's operation of the throttle 10.

The controller 160 may predict that at least one of the first and second throttle position sensors 111 and 113 is in a fault state when the difference between the voltage value acquired from the first throttle position sensor 111 and the voltage value acquired from the second throttle position sensor 113 exceeds a predetermined threshold value according to the driver's operation of the throttle 10.

For example, the predetermined threshold value may be predetermined as a maximum difference value between voltage values acquired from the first and second throttle position sensors 111 and 113 in a normal state and stored in a memory 161 to be described later, and the predetermined threshold value may be changed by an administrator or the like.

When the controller 160 predicts that at least one of the first and second throttle position sensors 111 and 113 is in a fault state, it may perform an operation to determine whether the first throttle position sensor 111 is actually in a fault state, whether the second throttle position sensor 113 is in a fault state, whether both the first and second throttle position sensors 111 and 113 are in fault states, or whether both the first and second throttle position sensors 111 and 113 are in normal states.

For example, when the difference between the voltage value acquired from the first throttle position sensor 111 and the voltage value acquired from the second throttle position sensor 113 exceeds a predetermined threshold value, the controller 160 may identify a first change amount of the voltage value of the first throttle position sensor 111 and a second change amount of the voltage value of the second throttle position sensor 113.

The controller 160 may identify whether the first change amount and the second change amount respectively are included in a predetermined threshold range of voltage change in order to identify whether the first and second throttle position sensors 111 and 113 are actually in a fault state.

The predetermined threshold range of voltage change may be designated as equal to or less than the maximum voltage change amount and equal to or greater than the minimum voltage change amount when each throttle position sensor 111 and 113 is in a normal state, and may be stored in a memory 161 to be described later. In addition, the predetermined threshold range of voltage change may be changed by an administrator or the like.

When the first change amount is included in the predetermined threshold range of voltage change, the controller 160 may determine the first throttle position sensor 111 to be in a normal state.

The controller 160 may determine the second throttle position sensor 113 to be in a normal state when the second change amount is included in the predetermined threshold range of voltage change.

The controller 160 may determine the first throttle position sensor 111 to be in a fault state when the first change amount is not included in the predetermined threshold range of voltage change.

The controller 160 may determine the second throttle position sensor 113 to be in a fault state when the second change amount is not included in the predetermined threshold range of voltage change.

The controller 160 may control the vehicle 1, that is, the driving device 120, based on the voltage value acquired from the first throttle position sensor 111 when the first throttle position sensor 111 is in a normal state and the second throttle position sensor 113 is in a fault state.

For example, when the first throttle position sensor 111 is in a normal state and the second throttle position sensor 113 is in a fault state, the controller 160 may determine the first throttle position sensor 111 as the main sensor. The controller 160 may control the driving device 120 based on the voltage value acquired from the determined main sensor, the first throttle position sensor 111.

For example, the controller 160 may determine the required torque of the vehicle 1 based on the voltage value acquired from the first throttle position sensor 111, and control the driving device 120 based on this. The technology for determining the required torque of the vehicle based on the voltage value of the position sensor is prior art, and detailed description thereof is omitted.

When the first throttle position sensor 111 is in a normal state and the second throttle position sensor 113 is in a fault state, the controller 160 may control the output device 150 so that information indicating that the second throttle position sensor 113 is in a fault state is output through the output device 150 to allow the driver to recognize this.

The controller 160 may control the vehicle 1, that is, the driving device 120, based on the voltage value acquired from the second throttle position sensor 113 when the first throttle position sensor 111 is in a fault state and the second throttle position sensor 113 is in a normal state.

For example, when the first throttle position sensor 111 is in a fault state and the second throttle position sensor 113 is in a normal state, the controller 160 may determine the second throttle position sensor 113 as the main sensor. The controller 160 may control the driving device 120 based on the voltage value acquired from the determined main sensor, the second throttle position sensor 113.

For example, the controller 160 may determine the required torque of the vehicle 1 based on the voltage value acquired from the second throttle position sensor 113, and control the driving device 120 based on this. The technology for determining the required torque of the vehicle based on the voltage value of the position sensor is prior art, and detailed description thereof is omitted.

The controller 160 may control the output device 150 so that information indicating that the first throttle position sensor 111 is in a fault state is output through the output device 150 so that the driver can recognize the matter, when the first throttle position sensor 111 is in a fault state and the second throttle position sensor 113 is in a normal state.

The controller 160 may control the vehicle 1 based on the voltage value acquired from the first throttle position sensor 111 and/or the second throttle position sensor 113 when both the first and second throttle position sensors 111 and 113 are in a normal state.

For example, the controller 160 may control the driving device 120 based on the average value of the voltage value acquired from the first throttle position sensor 111 and the voltage value acquired from the second throttle position sensor 113 when both the first and second throttle position sensors 111 and 113 are in a normal state.

For example, the controller 160 may determine the required torque of the vehicle 1 based on the average value, and control the driving device 120 based on this. Determining the required torque of the vehicle 1 based on the average value may be performed by applying the conventional technology of determining the required torque of the vehicle based on the voltage value of the position sensor.

As another example, one of the first throttle position sensor 111 and the second throttle position sensor 113 may be previously designated as the main sensor. Accordingly, when both the first and second throttle position sensors 111 and 113 are in a normal state, the controller 160 may control the driving device 120 based on the voltage value of either one of the position sensors previously designated as the main sensor.

When both the first and second throttle position sensors 111 and 113 are in a fault state, the controller 160 may control the vehicle 1 in a predetermined fault mode.

For example, the predetermined fault mode may include determining the required torque of the vehicle 1 as zero. This causes the acceleration of the vehicle 1 to become zero, allowing the vehicle 1 to maintain the current speed or decelerate.

In addition, the predetermined fault mode may further include controlling the output device 150 so that a notification indicating that both the first and second throttle position sensors 111 and 113 are in a fault state is output.

In addition, the predetermined fault mode may further include controlling the braking device 130 so that the vehicle 1 gradually decreases speed and comes to a stop.

The controller 160 may include a memory 161 and/or a processor 163.

For example, the controller 160 may be an electronic control unit ECU (Electronic Control Unit).

The memory 161 may store or record programs and data for implementing operations that control the components included in the controller 160, that is, for implementing operations that control the controller 160.

The memory 161 may provide the stored programs and data to the processor 163 and may record temporary data generated during the operation of the processor 163.

For example, the memory 161 may include non-volatile memories such as ROM (Read Only Memory), EPROM (Erasable Programmable Read Only Memory), EEPROM (Electrically Erasable Programmable Read-Only Memory), and flash memory.

Additionally, the memory 161 may further include volatile memories such as S-RAM (Static Random Access Memory) and D-RAM (Dynamic Random Access Memory).

The processor 163 may provide signals to control the operation of components included in the vehicle 1.

The processor 163 may be electrically connected or communicatively connected to the first throttle position sensor 111 and/or the second throttle position sensor 113, and may receive and process signals from each sensor.

The processor 163 may output signals to control the vehicle 1, for example, the driving device 120, braking device 130, and/or output device 150 of the vehicle 1, based on the processed signals received from each of the first throttle position sensor 111 and/or the second throttle position sensor 113.

Meanwhile, although omitted in the above embodiment of FIG. 1, the vehicle 1 may further include a power supply unit (not shown), for example, one or more batteries (not shown). Accordingly, each component of the vehicle 1, for example, the first throttle position sensor 111, the second throttle position sensor 113, the driving device 120, the braking device 130, the steering device 140, the output device 150, and/or the controller 160, may be supplied with power from the power supply unit through a power line.

For example, when the power supply unit of the vehicle 1 includes a first battery (not shown) and a second battery (not shown), and the first battery is predetermined as the main battery and the second battery as the auxiliary battery, each of the first throttle position sensor 111, the second throttle position sensor 113, the driving device 120, the braking device 130, the steering device 140, the output device 150, and/or the controller 160 may be connected to each of the first battery and the second battery through power supply lines.

Accordingly, each component of the vehicle 1 may be supplied with power from the first battery, and when the first battery is discharged or malfunctions, power may be supplied from the second battery.

Alternatively, when the power supply unit of the vehicle 1 includes the first battery and the second battery, the first throttle position sensor 111 may be supplied with power from the first battery through a power supply line, and the second throttle position sensor 113 may be supplied with power from the second battery through a power supply line. In addition, the driving device 120, the braking device 130, the steering device 140, the output device 150, and/or the controller 160 may each be supplied with power from the first battery and the second battery through power supply lines.

Accordingly, when one of the first and second batteries is discharged or malfunctions, the throttle position sensor that is supplied with power from the remaining battery may be used for controlling the vehicle 1.

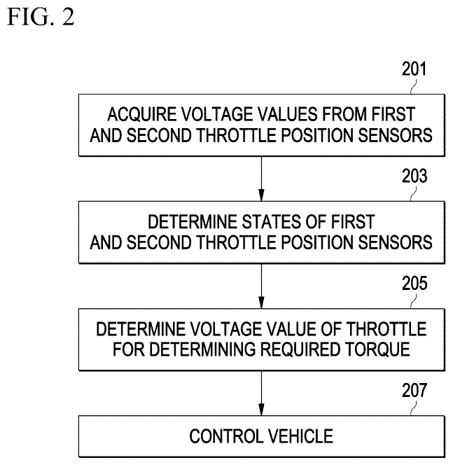

FIG. 2 is a flowchart of the operation of a vehicle according to an embodiment.

Referring to FIG. 2, the vehicle 1 may acquire voltage values from the first and second throttle position sensors 111 and 113 (201).

When the throttle 10 is operated by the driver, the first and second throttle position sensors 111 and 113 may output voltage values corresponding to the displacement of the throttle 10. Accordingly, the vehicle 1 may acquire voltage values corresponding to the displacement of the throttle 10 from each of the first and second throttle position sensors 111 and 113.

The vehicle 1 may determine the states of the first and second throttle position sensors 111 and 113 based on the voltage values acquired from the first and second throttle position sensors 111 and 113 (203).

The vehicle 1, in consideration of the possibility of momentary noise generation and sensor recovery, may continuously monitor, that is, identify, the voltage values of the first and second throttle position sensors 111 and 113, even if one of the first and second throttle position sensors 111 and 113 became the main sensor used for controlling the speed of the vehicle 1 in the previous step (also referred to as an operation cycle).

The vehicle 1 may determine whether each of the first and second throttle position sensors 111 and 113 is in a normal state or a fault state based on the voltage values acquired from the first and second throttle position sensors 111 and 113.

In addition, the vehicle 1 may determine whether each of the first and second throttle position sensors 111 and 113 is in a normal state or a fault state based on the amount of change in the voltage values acquired from each of the first and second throttle position sensors 111 and 113.

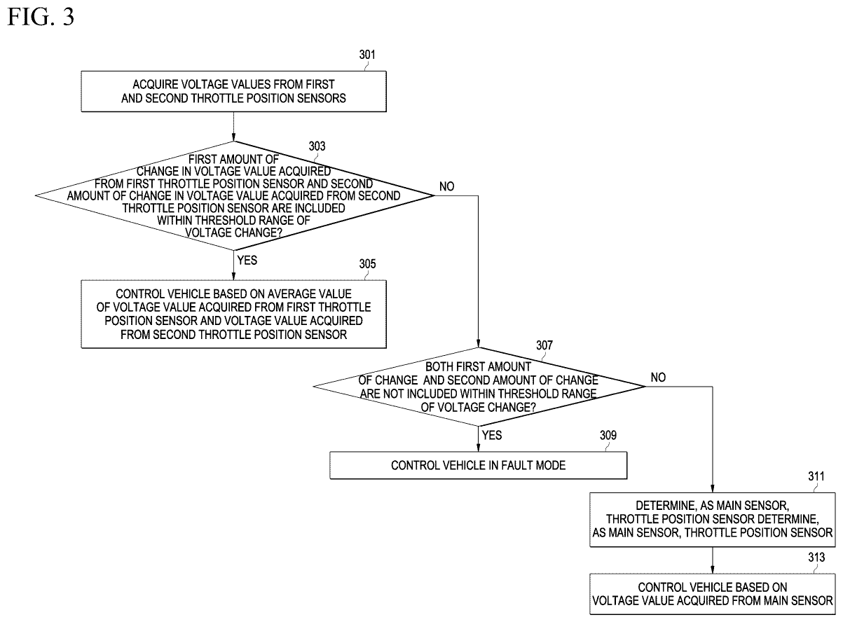

Detailed embodiments for determining whether each of the first and second throttle position sensors 111 and 113 is in a normal state or a fault state are described later with reference to FIG. 3, and thus detailed explanation is omitted.

The vehicle 1 may determine the voltage value of the throttle 10 for determining the required torque of the vehicle 1 based on the determination of the states of the first and second throttle position sensors 111 and 113 (205).

The vehicle 1 may determine the voltage value of the throttle 10 based on the voltage value acquired from the first throttle position sensor 111 and/or the voltage value acquired from the second throttle position sensor 113, in the case where both the first and second throttle position sensors 111 and 113 are in a normal state.

The vehicle 1 may determine the voltage value acquired from the first throttle position sensor 111 as the voltage value of the throttle 10, in the case where the first throttle position sensor 111 is in a normal state and the second throttle position sensor 113 is in a fault state.

The vehicle 1 may determine the voltage value acquired from the second throttle position sensor 113 as the voltage value of the throttle 10, in the case where the first throttle position sensor 111 is in a fault state and the second throttle position sensor 113 is in a normal state.

The vehicle 1 may determine the voltage value of the throttle 10 to be 0 in the case where both the first and second throttle position sensors 111 and 113 are in a fault state.

The vehicle 1 may control the vehicle 1 based on the determined voltage value of the throttle 10 (207).

The vehicle 1 may determine the required torque of the vehicle 1 based on the determined voltage value of the throttle 10.

For example, the vehicle 1 may determine the required torque of the vehicle 1 based on, in addition to the voltage value of the throttle 10, the engine speed, temperature, air flow rate, and/or fuel pressure of the vehicle 1. The determination of the required torque of the vehicle 1 is a conventional technique, and a detailed description is omitted.

The voltage value of the throttle 10 and the required torque of the vehicle 1 are in a proportional relationship, such that the required torque of the vehicle 1 may increase as the voltage value of the throttle 10 increases, and the required torque of the vehicle 1 may decrease as the voltage value of the throttle 10 decreases.

The vehicle 1 may control the vehicle 1, that is, may control the driving device 120 of the vehicle 1 based on the determined required torque.

Meanwhile, in addition to the embodiment of FIG. 2 described above, the vehicle 1 may not execute the operations of the embodiment of FIG. 2 described above in the case where no voltage value is output from both the first throttle position sensor 111 and the second throttle position sensor 113.

In addition, the operation of the vehicle 1 according to the embodiment of FIG. 2 described above may be executed during driving of the vehicle 1.

In addition, in addition to the embodiment of FIG. 2 described above, the vehicle 1 may enable the driver to recognize the fact in the case where there is a sensor that is determined to be in a fault state according to the state determination of the first and second throttle position sensors 111 and 113.

For example, the vehicle 1 may output information indicating that the throttle position sensor determined to be in a fault state is in a fault state through the output device 150.

As another example, the vehicle 1 may further include a communication device (also referred to as a communication circuit) (not shown), and may be communicatively connected through the communication device to a server (not shown) that manages the vehicle 1 and/or an electronic device of the driver of the vehicle 1 (e.g., a smartphone, etc.) (not shown). The vehicle 1 may transmit information indicating that the throttle position sensor determined to be in a fault state is in a fault state to the communicatively connected server and/or the electronic device.

FIG. 3 is a flowchart of the operation of a vehicle according to an embodiment.

Referring to FIG. 3, the vehicle 1 may acquire voltage values from the first and second throttle position sensors 111 and 113 (301).

While the vehicle 1 is travelling, the driver may operate the throttle 10 to increase the speed of the vehicle 1.

When the throttle 10 is operated by the driver, the first and second throttle position sensors 111 and 113 may output voltage values corresponding to the displacement of the throttle 10.

The vehicle 1 may acquire voltage values corresponding to the displacement of the throttle 10 from each of the first and second throttle position sensors 111 and 113.

The vehicle 1 may identify whether a first amount of change in a voltage value acquired from the first throttle position sensor 111 and a second amount of change in a voltage value acquired from the second throttle position sensor 113 are included within a predetermined threshold range of voltage change (303).

For example, the vehicle 1 may identify whether a difference between the voltage value acquired from the first throttle position sensor 111 and the voltage value acquired from the second throttle position sensor 111 exceeds a predetermined threshold value.

If the difference between the voltage value acquired from the first throttle position sensor 111 and the voltage value acquired from the second throttle position sensor 111 exceeds the predetermined threshold value, the vehicle 1 may identify the first amount of change in the voltage value acquired from the first throttle position sensor 111 and the second amount of change in the voltage value acquired from the second throttle position sensor 113.

The vehicle 1 may execute operation 305 if the first amount of change and the second amount of change are included within a predetermined threshold range of voltage change, and otherwise may execute operation 307.

The vehicle 1 may control the vehicle 1 based on an average value of the voltage value acquired from the first throttle position sensor 111 and the voltage value acquired from the second throttle position sensor 113 (305).

For example, the vehicle 1 may determine the required torque of the vehicle 1 based on the average value and control the driving device 120 based on the determined torque.

The vehicle 1 may identify whether both the first amount of change and the second amount of change are not included within the predetermined threshold range of voltage change (307).

If both the first amount of change and the second amount of change are not included within the predetermined threshold range of voltage change, the vehicle 1 may execute operation 309, and otherwise may execute operation 311.

The vehicle 1 may control the vehicle 1 in a predetermined fault mode (309).

The vehicle 1 may set the required torque to zero, that is, to make the acceleration of the vehicle 1 zero, so that the vehicle 1 may maintain its current speed or decelerate.

Additionally, the vehicle 1 may control the output device 150 so that a notification indicating that both the first and second throttle position sensors 111, 113 are in a fault state is output, allowing the driver to recognize this fact.

Furthermore, the vehicle 1 may control the braking device 130 so that the speed of the vehicle 1 gradually decreases and then stops.

The vehicle 1 may determine, as the main sensor, the throttle position sensor among the first throttle position sensor 111 and the second throttle position sensor 113 whose voltage change amount is included within the threshold range (311).

The vehicle 1 may control the vehicle 1 based on the voltage value acquired from the main sensor (313).

For example, the vehicle 1 may determine the required torque of the vehicle 1 based on the voltage value acquired from the main sensor, and control the driving device 120 based on this.

Meanwhile, in the above-described embodiment of FIG. 3, when both the first and second throttle position sensors 111 are in a normal state, the vehicle 1 determines the required torque based on the average value of the voltage values acquired from the first throttle position sensor 111 and the second throttle position sensor 113, and controls the driving device 120.

However, according to another embodiment, when both the first and second throttle position sensors 111 are in a normal state, the vehicle 1 may determine the required torque based on the voltage value acquired from the main sensor determined in the previous cycle or the sensor predetermined as the main sensor, and control the driving device 120.

According to the above-described embodiments, the vehicle 1 is provided with the first throttle position sensor 111 and the second throttle position sensor 113, thereby providing a redundancy function of the throttle position sensors.

Accordingly, when either the first throttle position sensor 111 or the second throttle position sensor 113 fails or an error occurs, the other sensor may perform the corresponding function, thereby ensuring the stability and reliability of the vehicle 1.

In addition, since the vehicle 1 can compare the voltage value acquired from the first throttle position sensor 111 with the voltage value acquired from the second throttle position sensor 113, the vehicle 1 can acquire a more accurate voltage value to be applied to the control of the vehicle 1.

For example, when the voltage values acquired from the first and second throttle position sensors 111 and 113 are not similar (or do not match), it may be predicted that at least one of the first throttle position sensor 111 and the second throttle position sensor 113 is in a fault state, and appropriate measures may be taken.

Accordingly, the accuracy of the vehicle 1 control according to the displacement of the throttle of the vehicle 1 may be improved.

The vehicle 1 and its control method according to the above-described embodiments include multiple throttle position sensors that output voltage values corresponding to the displacement of the throttle, and control the vehicle after determining the state of each of the multiple throttle position sensors, thereby enabling safe driving of the vehicle.

The vehicle 1 and its control method according to the above-described embodiments can identify the throttle voltage through the remaining sensors when a failure occurs in any one of the multiple throttle position sensors, thereby improving the riding comfort of the vehicle's driver.

The vehicle 1 and its control method according to the above-described embodiments can provide a stable vehicle control technology that considers noise occurrence and recovery situations in the signals of the throttle position sensors.

Meanwhile, the disclosed embodiments may be implemented in the form of a recording medium that stores instructions executable by a computer. The instructions may be stored in the form of program codes, and when executed by a processor, can generate a program module to perform the operations of the disclosed embodiments. The recording medium may be implemented as a computer-readable recording medium.

Computer-readable recording media include all types of recording media that store instructions that can be deciphered by a computer. Examples include read only memory (ROM), random access memory (RAM), magnetic tape, magnetic disk, flash memory, and optical data storage devices.

A storage medium that can be read by the device may be provided in the form of a non-transitory storage medium. Here, “non-transitory” means only that the storage medium is a tangible device and does not contain signals (for example, electromagnetic waves), and this term does not distinguish between cases where data is stored semi-permanently in the storage medium and cases where data is stored temporarily. For example,

a “non-transitory storage medium” may include a buffer in which data is temporarily stored.

The disclosed embodiments have been described with reference to the attached drawings as described above.

Those skilled in the art will understand that the present disclosure can be implemented in forms other than the disclosed embodiments without changing the technical idea or essential features of present disclosure.

The disclosed embodiments are exemplary and should not be construed as limiting.

What is claimed is:

1. A vehicle comprising:
a first throttle position sensor configured to output a voltage value corresponding to a displacement of a throttle;
a second throttle position sensor configured to output a voltage value corresponding to a displacement of the throttle; and
a controller electrically connected to the first throttle position sensor and the second throttle position sensor,
wherein
the controller is configured to:
identify whether a first change amount of the voltage value obtained from the first throttle position sensor and a second change amount of the voltage value obtained from the second throttle position sensor are within a predetermined threshold range of a voltage change amount, and
control the vehicle based on a voltage value obtained from at least one of the first throttle position sensor or second throttle position sensor in response to at least one of the first change amount or the second change amount being within the predetermined threshold range of the voltage change amount.

2. The vehicle according to 1, wherein the controller is configured to:
determine a required torque of the vehicle based on the voltage value obtained from at least one of the first throttle position sensor or second throttle position sensor, and
control a speed of the vehicle based on the required torque.

3. The vehicle according to 2, wherein the controller is configured to identify the first change amount and the second change amount based on a difference between the voltage value obtained from the first throttle position sensor and the voltage value obtained from the second throttle position sensor exceeding a predetermined threshold value.

4. The vehicle according to 3, wherein the controller is configured to control speed of the vehicle, based on an average value of the voltage value obtained from the first throttle position sensor and the voltage value obtained from the second throttle position sensor, in response to the difference between the voltage value obtained from the first throttle position sensor and the voltage value obtained from the second throttle position sensor being less than or equal to the predetermined threshold value.

5. The vehicle according to 2, wherein the controller is configured to control speed of the vehicle, based on an average value of the voltage value obtained from the first throttle position sensor and the voltage value obtained from the second throttle position sensor, in response to the first change amount and the second change amount being within the predetermined threshold range.

6. The vehicle according to 2, wherein the controller is configured to control speed of the vehicle, based on the voltage value obtained from the first throttle position sensor, in response to the first change amount being within the predetermined threshold range and the second change amount not being within the predetermined threshold range.

7. The vehicle according to 6, wherein the controller is configured to control speed of the vehicle, based on the voltage value obtained from the second throttle position sensor, in response to the first change amount not being within the predetermined threshold range and the second change amount being within the predetermined threshold range.

8. The vehicle according to 1, wherein the controller is configured to control the vehicle in a predetermined fault mode in response to the first change amount and the second change amount not being within the predetermined threshold range.

9. The vehicle according to 8, wherein the controller is configured to determine a required torque of the vehicle to be zero, in response to the first change amount and the second change amount not being within the predetermined threshold range.

10. The vehicle according to 9, wherein the controller is configured to control an output device of the vehicle to output a notification indicating that the first throttle position sensor and the second throttle position sensor are in a fault state, in response to the first change amount and the second change amount not being within the threshold range.

11. A control method of vehicle comprising:
identifying whether a first change amount of the voltage value obtained from a first throttle position sensor configured to output a voltage value corresponding to a displacement of a throttle and a second change amount of the voltage value obtained from a second throttle position sensor configured to output a voltage value corresponding to a displacement of the throttle are within a predetermined threshold range of a voltage change amount, and
controlling the vehicle based on a voltage value obtained from at least one of the first throttle position sensor or second throttle position sensor in response to at least one of the first change amount or the second change amount being within the predetermined threshold range of the voltage change amount.

12. The control method according to 11, wherein controlling of the vehicle comprises:
determining a required torque of the vehicle based on the voltage value obtained from at least one of the first throttle position sensor or second throttle position sensor, and
controlling a speed of the vehicle based on the required torque.

13. The control method according to 12, further comprising:
identifying the first change amount and the second change amount based on a difference between the voltage value obtained from the first throttle position sensor and the voltage value obtained from the second throttle position sensor exceeding a predetermined threshold value.

14. The control method according to 13, further comprising:
controlling speed of the vehicle, based on an average value of the voltage value obtained from the first throttle position sensor and the voltage value obtained from the second throttle position sensor, in response to the difference between the voltage value obtained from the first throttle position sensor and the voltage value obtained from the second throttle position sensor being less than or equal to the predetermined threshold value.

15. The control method according to 12, wherein controlling of the speed of the vehicle is performed based on an average value of the voltage value obtained from the first throttle position sensor and the voltage value obtained from the second throttle position sensor,
in response to the first change amount and the second change amount being within the predetermined threshold range.

16. The control method according to 12, wherein controlling of the speed of the vehicle is performed based on the voltage value obtained from the first throttle position sensor, in response to the first change amount being within the predetermined threshold range and the second change amount not being within the predetermined threshold range.

17. The control method according to 16, wherein controlling of the speed of the vehicle is performed based on the voltage value obtained from the second throttle position sensor, in in response to the first change amount not being within the predetermined threshold range and the second change amount being within the predetermined threshold range.

18. The control method according to 11, further comprising:
controlling the vehicle in a predetermined fault mode, in response to the first change amount and the second change amount not being within the predetermined threshold range.

19. The control method according to 18, wherein controlling of the vehicle in the predetermined fault mode comprises:
determining a required torque of the vehicle to be zero.

20. The control method according to 19, wherein controlling of the vehicle in the predetermined fault mode comprises:
controlling an output device of the vehicle to output a notification indicating that the first throttle position sensor and the second throttle position sensor are in a fault sta
